(19) United States
(12) Patent Application Publication
(10) Pub. No.: US 2014/0285060 A1
(43) Pub. Date: Sep. 25, 2014

(54) ELECTRICAL COMPONENT AND METHOD OF MANUFACTURING THE SAME

(71) Applicant: KABUSHIKI KAISHA TOSHIBA, Tokyo (JP)

(72) Inventor: Hiroaki YAMAZAKI, Yokohama-shi (JP)

(21) Appl. No.: 14/021,826

(22) Filed: Sep. 9, 2013

(30) Foreign Application Priority Data
Mar. 25, 2013 (JP) 2013-062591

(51) Int. Cl. B81B 7/00; B81C 1/00; B81B 3/00

(52) U.S. Cl. CPC B81B 7/00; B81B 3/0021; B81B 3/0072; B81C 1/00531; B81C 1/00666
USPC 310/300; 216/13

(57) ABSTRACT

According to one embodiment, there is disclosed an electrical component. The electrical component includes a substrate, a MEMS device on the substrate. The MEMS device includes a first electrode fixed on the substrate, a second electrode above the first electrode opposed to the first electrode and configured to be movable, an anchor member on the substrate and configured to support the second electrode, and a spring member continuously formed from a region on an upper surface of the second electrode to a region on an upper surface of the anchor member and configured to connect the second electrode and the anchor member. The electrical component includes a reinforcing member provided on a lower surface of the spring member and configured to reinforce strength of the spring member.

### CROSS-REFERENCE TO RELATED APPLICATIONS

This application is based upon and claims the benefit of priority from Japanese Patent Application No. 2013-062591, filed Mar. 25, 2013, the entire contents of which are incorporated herein by reference.

### FIELD

Embodiments described herein relate generally to an electrical component including a MEMS device and a method of manufacturing the same.

### BACKGROUND

Micro-electro-mechanical systems (MEMS) devices formed of a movable electrode and a fixed electrode have been attracting attention as key devices of next-generation mobile telephones, since such MEMS devices have low-loss and high-linearity characteristics. In such a HEMS device, a low-resistance metal material such as aluminum (Al) should desirably be used in the electrode part.

An electrode structure needs to be driven up and down in a MEMS device. The material such as Al used as the movable electrode is ductile. Therefore, when the movable electrode which uses Al, for example, is repeatedly driven, the movable electrode cannot maintain the initial structure due to creep phenomenon (change in shape under the influence of a stress) and deformation occurs in the structure of the movable electrode. Such deformation in structure makes it difficult to realize a MEMS device having a structure with desired characteristics.

In order to prevent occurrence of the above-described problem of deformation in structure, it is also possible to use a material that has a plastic deformation ratio lower than that of Al, such as tungsten (W), as the movable electrode. However, the low-resistance characteristics of MEMS are lost due to the high resistance value of W.

In order to solve the above-described problem of deformation in structure, a method has been proposed to use a brittle material as a material of a spring member that connects the movable electrode formed of a ductile material and a supporting member (anchor member) to support the movable electrode.

According to this method, since the material of the spring member connected to the movable electrode is brittle, creep phenomenon, which causes deformation in structure, is considered not to occur even if the movable electrode is driven. Even by adopting this method, however, the problem of deformation in structure may occur.

### BRIEF DESCRIPTION OF THE DRAWINGS

FIG. 1 is a plane view schematically illustrating a MEMS device according to an embodiment;

FIG. 2 is a cross-sectional view taken along the direction of arrows of FIG. 1;

FIG. 3 is a cross-sectional view illustrating a method of manufacturing the MEMS device according to the embodiment;

FIG. 4 is a cross-sectional view illustrating the method of manufacturing the MEMS device according to the embodiment, subsequent to FIG. 3;

FIG. 5 is a cross-sectional view illustrating the method of manufacturing the MEMS device according to the embodiment, subsequent to FIG. 4;

FIG. 6 is a cross-sectional view illustrating the method of manufacturing the MEMS device according to the embodiment, subsequent to FIG. 5;

FIG. 7 is a cross-sectional view illustrating the method of manufacturing the MEMS device according to the embodiment, subsequent to FIG. 6;

FIG. 8 is a cross-sectional view illustrating the method of manufacturing the MEMS device according to the embodiment, subsequent to FIG. 7;

FIG. 9 is a cross-sectional view illustrating the method of manufacturing the MEMS device according to the embodiment, subsequent to FIG. 8;

FIG. 10 is a cross-sectional view illustrating the method of manufacturing the MEMS device according to the embodiment, subsequent to FIG. 9;

FIG. 11 is a cross-sectional view illustrating the method of manufacturing the MEMS device according to the embodiment, subsequent to FIG. 10;

FIG. 12 is a cross-sectional view illustrating the method of manufacturing the MEMS device according to the embodiment, subsequent to FIG. 11;

FIG. 13 is a cross-sectional view illustrating the method of manufacturing the MEMS device according to the embodiment, subsequent to FIG. 12;

FIG. 14 is a cross-sectional view schematically showing a modification of a second anchor member of the MEMS device according to the embodiment;

FIG. 15 is a cross-sectional view illustrating a problem of method of manufacturing a MEMS device according to a comparative example;

FIG. 16 is a cross-sectional view illustrating the problem of the method of manufacturing the MEMS device according to the comparative example, subsequent to FIG. 15;

FIG. 17 is a cross-sectional view illustrating the problem of the method of manufacturing the MEMS device according to the comparative example, subsequent to FIG. 16;

FIG. 18 is a plane view schematically illustrating another plane pattern of the second spring member of the MEMS device according to the embodiment;

FIG. 19 is a plane view schematically illustrating yet another plane pattern of the second spring member of the MEMS device according to the embodiment;

FIGS. 20A and 20B are plane views schematically illustrating another exemplary layout of a reinforcing member of the MEMS device according to the embodiment;

FIGS. 21A, 21B, and 21C are plane views schematically illustrating yet another exemplary layout of the reinforcing member of the MEMS device according to the embodiment;

FIG. 22 is a view for explaining conditions for isotropic etching of a metal layer in the method of manufacturing the MEMS device according to the embodiment;

FIG. 23 a view for explaining conditions for isotropic etching of a metal layer in the method of manufacturing the MEMS device according to the embodiment; and

FIG. 24 is a plane view schematically illustrating a modification of a hole portion of the MEMS device according to the embodiment.

### DETAILED DESCRIPTION

An embodiment will now be described with reference to the accompanying drawings. The same structural elements will be denoted by same reference numerals throughout the drawings, and repetitive descriptions will be made only when necessary.

According to an aspect, there is provided an electrical component. The electrical component includes a substrate; and a MEMS device provided on the substrate. The MEMS device includes a first electrode fixed on the substrate; a second electrode arranged above the first electrode so as to be opposed to the first electrode and configured to be movable in a vertical direction; an anchor member provided on the substrate and configured to support the second electrode; a spring member continuously formed from a region on an upper surface of the second electrode to a region on an upper surface of the anchor member and configured to connect the second electrode and the anchor member; and a reinforcing member provided on a lower surface of the spring member and configured to reinforce strength of the spring member.

According to another aspect, there is provided a method of manufacturing an electrical component including a method of manufacturing a MEMS device on a substrate. The method of manufacturing the MEMS device includes forming a first electrode fixed on the substrate; forming a first sacrifice layer on an entire surface; forming a metal layer on the first sacrifice layer; forming a spring member on the metal layer; and forming a second electrode and an anchor member which are connected by the spring member, and forming a reinforcing member configured to reinforce strength of the spring member on a lower surface of the spring member, by etching the metal layer.

### First Embodiment

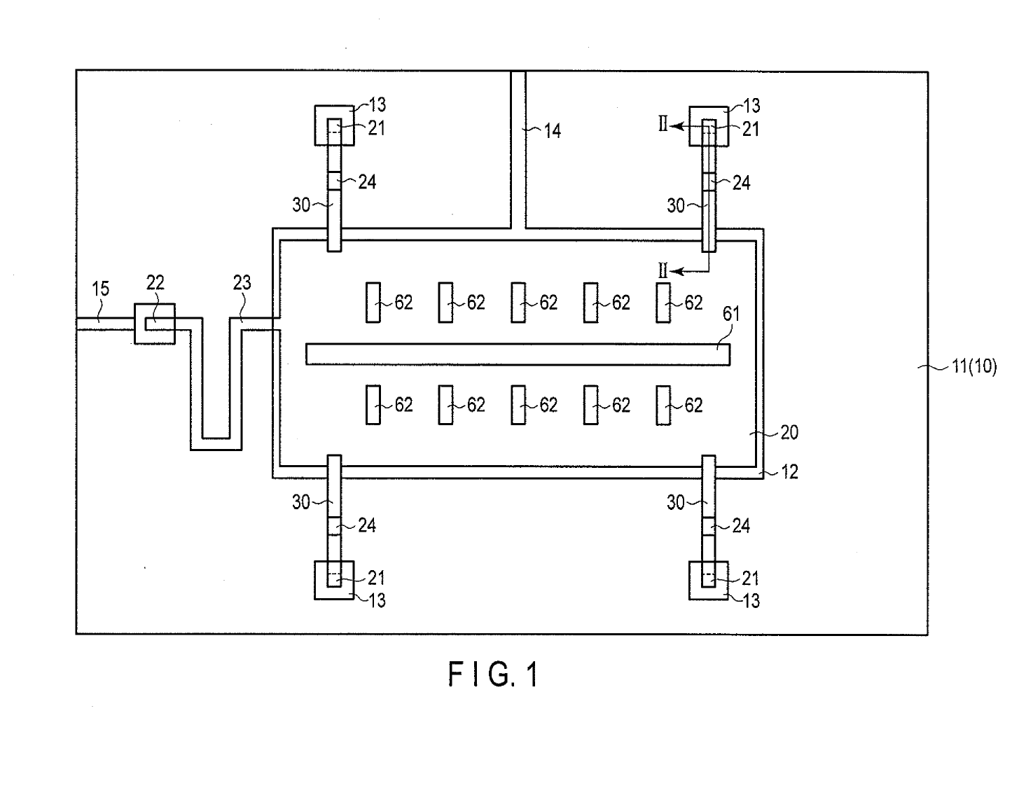

FIG. 1 is a plane view illustrating a structure of a MEMS device according to the present embodiment.

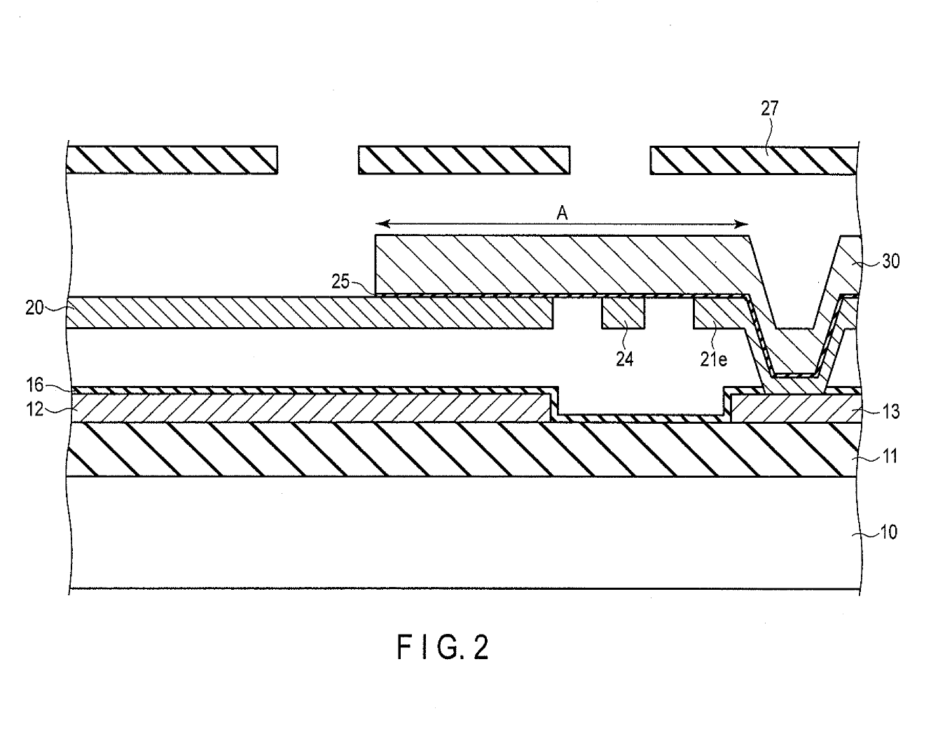

FIG. 2 is a cross-sectional view taken along the direction of arrows II-II of FIG. 1, illustrating a structure of the MEMS device according to the embodiment.

In the MEMS device according to the present embodiment, a second spring member 30 connecting an upper electrode 20 and a second anchor member 21 is continuously formed from a region on an upper surface of the upper electrode 20 to a region on an upper surface of the second anchor member 21, a lower surface of the second spring member 30 is smoothly formed, preferably horizontally without steps, in the regions therebetween, in addition, a reinforcing member 24 configured to reinforce strength of the second spring member 30 is formed on the lower surface of the second spring member 30 so as to suppress deformation of the upper electrode 20 involved with deformation of the second spring member 30 during manufacturing (during a curing, during removing a sacrifice layer). Thereby, the upper electrode 20 can be formed in a shape with desired characteristics in the MEMS device. Details on the present embodiment will now be described below.

As shown in FIGS. 1 and 2, a MEMS device according to the present embodiment comprises a lower electrode 12 and an upper electrode 20 provided on an interlayer insulating layer 11 on a supporting substrate 10.

The supporting substrate 10 is a silicon substrate, for example. The interlayer insulating layer 11 is formed of a material having a low dielectric constant, for example, in order to suppress parasitic capacitance. This material is a silicon oxide (SiOx) derived from SiH₄ or tetraethyl orthosilicate (TEOS), for example. Furthermore, in order to suppress parasitic capacitance, a thickness of the interlayer insulating layer 11 should be large; the thickness of the interlayer insulating layer 11 is 10 μm or greater, for example.

Elements such as field-effect transistors may be provided on a surface of the supporting substrate 10. Such elements constitute a logic circuit, or storage circuit. The interlayer insulating layer 11 is provided on the supporting substrate 10 so as to cover such circuits. Accordingly, the MEMS device is provided above the circuits on the supporting substrate 10.

A circuit that causes noise, such as an oscillator, affects behavior of the MEMS device. In order to avoid the effect of noise, a circuit that causes noise should be arranged below the MEMS device, for example. Instead of the supporting substrate 10 and the interlayer insulating layer 11, an insulating substrate such as a glass substrate may be used. In the description that follows, the supporting substrate 10 and the interlayer insulating layer 11 will also be referred to as a substrate.

The lower electrode 12 is formed on the substrate and fixed. The lower electrode 12 has a flat-plate shape parallel to a surface of the substrate, for example. The lower electrode 12 is formed of aluminum (Al), an alloy containing Al as the main component, copper (Cu), gold (Au), or platinum (Pt). The lower electrode 12 is connected to a wiring 14 formed of a material same as that of the lower electrode 12. The lower electrode 12 is connected to a variety of circuits via the wiring 14. An insulating layer 16, formed of a silicon oxide (SiOx), a silicon nitride (SiN), or a high-k material, is formed on a surface of the lower electrode 12.

An upper electrode 20 is formed above the lower electrode 12, so as to be supported in a floating state and movable up and down (in a vertical direction relative to the substrate). The upper electrode 20 has a flat-plate shape parallel to the surface of the substrate, except that the upper electrode 20 includes a first hole portion 61 and second hole portions 62.

The first hole portion 61 has a rectangular shape, extending in a longitudinal direction (first direction) of the upper electrode 20. The first hole portion 61 is provided in an approximately center part in a lateral direction (second direction) of the upper electrode 20. The longitudinal direction of the upper electrode 20 and a longitudinal direction (first direction) of the first hole portion 61 are approximately parallel. Accordingly, the upper electrode 20 is more flexible in the lateral direction than in the longitudinal direction. Thereby, a pull-in voltage of the MEMS device can be reduced.

Each of the second hole portions 62 has a rectangular shape, and extends in the lateral direction of the upper electrode 20. The second hole portions 62 are provided between a peripheral part of the upper electrode 20 and the first hole portion 61 so as to interpose the first hole portion 61, and are approximately axisymmetric relative to the first hole portion 61. A longitudinal direction of the second hole portions 62 and the longitudinal direction of the upper electrode 20 are approximately orthogonal.

The layout of the first hole portion 61 and the second hole portions 62 is not limited to the layout shown in FIG. 1; a part of the second hole portions 62 may connected to the first hole portion 61, as shown in FIG. 24, for example. In FIG. 24, every other two second hole portions 62 facing each other in the vertical direction connects to the first hole portion 61.

The upper electrode 20 is arranged so as to be opposed to the lower electrode 12. That is, the upper electrode 20 overlaps with the lower electrode 12 in a plane (plane parallel to the surface of the substrate; hereinafter simply referred to as a plane) extending in the first direction (horizontal direction in FIG. 1), which is the longitudinal direction of the upper electrode 20, and the second direction (vertical direction in FIG. 1), which is the lateral direction of the upper electrode 20 and is orthogonal to the first direction.

The upper electrode 20 is formed of Al, an alloy containing Al as the main component, Cu, Au, or Pt, for example. That is, the upper electrode 20 is formed of a ductile material. When a member formed of a ductile material breaks under the influence of a stress, the member undergoes significant plastic deformation (extension) before breaking.

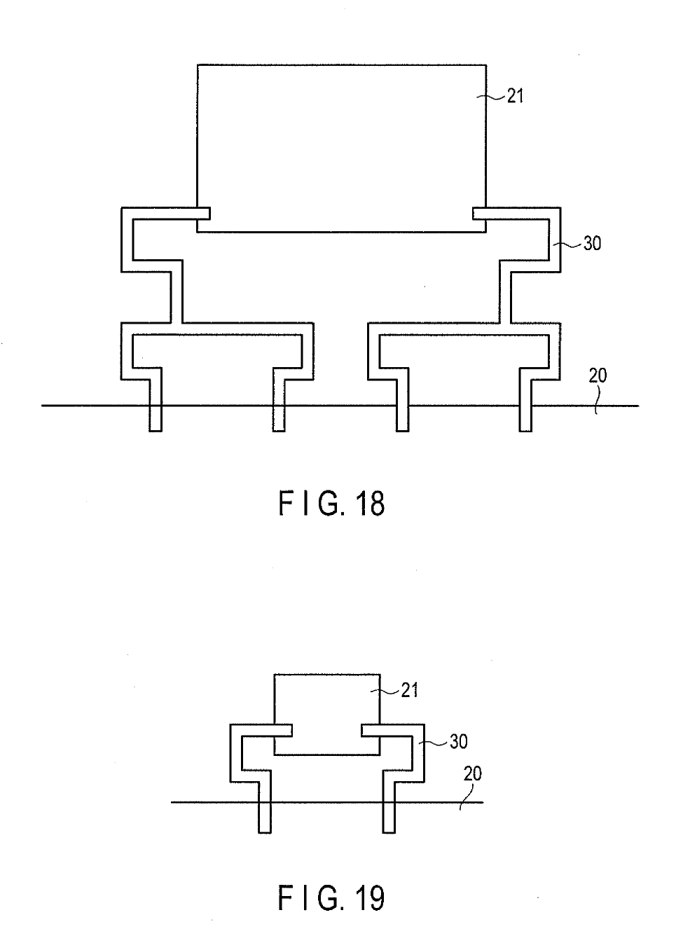

The shapes of the lower electrode 12 and the upper electrode 20 in the plane are rectangular in the drawings, but are not limited thereto, and may be square, circular, or oval. Further, an area of the lower electrode 12 in the plane is shown as being greater than an area of the upper electrode 20, but is not limited thereto. In the present embodiment, a planar pattern of the second spring member 30 has a line shape for the sake of simplicity, but is not limited thereto, and may be the planar patterns shown in FIGS. 18 and 19.

A first spring member 23 and second spring members 30 are connected to the movable upper electrode 20 supported in a floating state. The first spring member 23 and the second spring members 30 are formed of different materials. A first cap film 25 is formed on a lower surface (bottom surface) of each of the second spring members 30.

The first spring member 23 connects the upper electrode 20 and a first anchor member 22 supporting the upper electrode 20.

More specifically, one end of the first spring member 23 is connected to one end (edge) of the upper electrode 20 in the first direction. The first spring member 23 is integrally formed with the upper electrode 20, for example. That is, the upper electrode 20 and the first spring member 23 are connected in a form of a single-layer structure and are formed in a same level. The first spring member 23 has a meandering planar shape, for example. In other words, the first spring member 23 has an elongated, winding shape in the plane.

The first spring member 23 is formed of a conductive ductile material, for example, which is the same as the material of the upper electrode 20. That is, the first spring member 23 is formed of a metal material such as Al, an alloy containing Al as the main component, Cu, Au, or Pt.

The other end of the first spring member 23 is connected to a first anchor member 22. The first anchor member 22 supports the upper electrode 20. The first anchor member 22 is integrally formed with the first spring member 23, for example. Accordingly, the first anchor member 22 is formed of a conductive ductile material, for example, which is the same as the materials of the upper electrode 20 and the first spring member 23. The first anchor member 22 is formed of a metal material such as Al, an alloy containing Al as the main component, Cu, Au, or Pt. The first anchor member 22 may be formed of a material different from the materials of the upper electrode 20 and the first spring member 23.

The first anchor member 22 is provided on a wiring 15. The wiring 15 is provided on the interlayer insulating layer 11. A surface of the wiring 15 is covered with an insulating layer, not shown. The insulating layer is integrally formed with the insulating layer 16, for example. The insulating layer includes an opening portion, via which the first anchor member 22 directly contacts the wiring 15. That is, the upper electrode 20 is electrically connected to the wiring 15 via the first spring member 23 and the first anchor member 22, and connected to a variety of circuits. Thereby, a potential (voltage) is supplied to the upper electrode 20 via the wiring 15, the first anchor member 22, and the first spring member 23.

A second spring member 30 is connected to each of four corners (both ends in the first direction and the second direction) of the upper electrode 20 in a rectangular shape. The number of the second spring members 30 is four in this example, but is not limited thereto. The second spring member 30 connects the upper electrode 20 and a second anchor member 21 supporting the upper electrode 20. Details on the second spring members 30 according to the present embodiment will be described later.

The second anchor member 21 is provided on a dummy layer 13. The second anchor member 21 is formed of a conductive ductile material, for example, which is the same as the materials of the upper electrode 20 and the first spring member 23. The second anchor member 21 is formed of a metal material such as Al, an alloy containing Al as the main component, Cu, Au, or Pt. The second anchor member 21 may be formed of a material different from the materials of the upper electrode 20 and the first spring member 23.

The dummy layer 13 is provided on the interlayer insulating layer 11. A surface of the dummy layer 13 is covered with an insulating layer integrally formed with the insulating layer 16, for example. The insulating layer includes an opening portion, via which the second anchor member 21 contacts the dummy layer 13. While the second anchor member 21 directly contacts the dummy layer 13, the second anchor member 21 does not necessarily need to directly contact the dummy layer 13.

The wiring 15 and the dummy layer 13 are formed of a material same as the material of the lower electrode 12, for example. A thickness of the wiring 15 and the dummy layer 13 is comparable to a thickness of the lower electrode 12.

The second spring member 30 in the present embodiment is continuously formed from a region on an upper surface of the upper electrode 20 to a region an upper surface of the second anchor member 21, and is horizontally formed without steps in a region A extending from the upper surface of the upper electrode 20 to an upper surface of an edge 21e of the second anchor member 21 (on the side of the upper electrode 20). Here, a structure of a MEMS device in an initial operation state will be taken as an example.

More specifically, one end of the second spring member 30 is provided on the upper electrode 20 via the first cap film 25. Accordingly, the second spring member 30 is formed so as to contact the upper surface of the upper electrode via the first cap film 25, and a joint between the second spring member 30 and the upper electrode 20 has a laminated structure. The other end of the second spring member 30 is provided on the second anchor member 21 via the first cap film 25. Accordingly, the second spring member 30 is formed so as to contact an upper surface of the second anchor member 21 including a concave portion via the first cap film 25, and a joint between the second spring member 30 and the second anchor member 21 has a laminated structure. The upper electrode 20 is supported by the second anchor member 21.

The second spring member 30 is in a floating state in a region between the upper electrode 20 and the second anchor member 21. The second spring member 30 is horizontally formed in the region on the upper surface of the upper electrode 20, in the region on the upper surface of the edge 21e of the second anchor member 21, and in the region in which the second spring member 30 is in a floating state. In other words, a lower surface of the second spring member 30 is formed flat in the region on the upper surface of the upper electrode 20, in the region on the upper surface of the edge 21e of the second anchor member 21, and in the region in which the second spring member 30 is in a floating state. That is, since the upper surface of the upper electrode 20 and the upper surface of the edge 21e of the second anchor member 21 are in the same level (the same height), the second spring member 30 is formed in the same lever on the upper surface of the upper electrode 20, on the upper surface of the edge 21e of the second anchor member 21, and in the region where the second spring member 30 is in a floating state. Accordingly, a lower surface of the second spring member 30 is in the same level with the upper surfaces of the upper electrode 20 and the edge 21e of the second anchor member 21. In other words, the second spring member 30 does not have steps in an interface between the region on the upper surface of the upper electrode 20 and the region in which the second spring member 30 is in a floating state, and in an interface between the region on the upper surface of the edge 21e of the second anchor member 21 and the region in which the second spring member 30 is in a floating state. The upper surface of the second spring member 30 may be formed flat, as well as the lower surface. The second spring member 30 has a meandering planar shape, for example, in the region between the upper electrode 20 and the second anchor member 21.

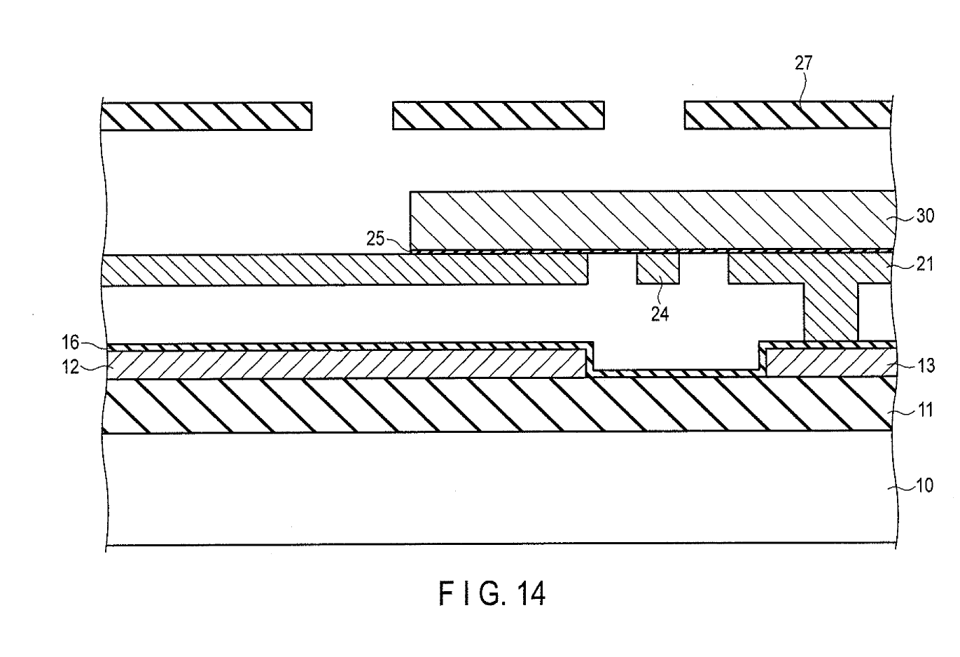

When the second anchor member 21 is formed in the shape of a plug, as shown in FIG. 14, since a surface of the second anchor member 21 under the lower surface of the second spring member 30 becomes flat, the lower surface of the second spring member 30 is formed flat in the region on the upper surface of the upper electrode 20, in the region on the upper surface of the second anchor member 21, and in the region in which the second spring member 30 is in a floating state. That is, the second spring member 30 connecting the upper electrode 20 and the second anchor member 21 is continuously formed from the region on the upper surface of the upper electrode 20 to the region on the upper surface of the second anchor member 21, so as to be horizontally formed without steps in a region therebetween.

With the above-described structure, the size of the step of the second spring member 30 becomes small compared to the conventional art, and deterioration in film quality caused by the step portion is suppressed. This suppresses cutting of the second spring member 30 and deterioration in durability as a result of the second spring member 30 being thinly formed. This is contributory to providing the MEMS device comprising the second spring member 30 in a shape with desired characteristics.

Further, in the MEMS device of the present embodiment, a reinforcing member 24 configured to reinforce strength of the second spring member 30 is formed on the lower surface of the second spring member 30. This makes it possible to suppress deformation such as curving of the second spring member 30 in a step of making the upper surface side of the second spring member 30 in a hollow state, as will be described later. This is also contributory to providing the MEMS device comprising the second spring member 30 in the shape with desired characteristics.

The second spring member 30 is formed of a brittle material, for example. When subjected to stress, a member formed of a brittle material breaks without significant plastic deformation (change in shape). Examples of brittle materials include silicon oxide (SiOx), silicon nitride (SiN), and a silicon oxynitride (SiON).

A spring constant k2 of the second spring member 30 which uses a brittle material is set to be greater than a spring constant k1 of the first spring member 23 which uses a ductile material, by appropriately setting at least one of a linewidth of the second spring member 30, a thickness of the second spring member 30, and a curved portion (flexure) of the second spring member 30. Desirably, SiN, which has a relatively large elastic constant, should be used as the brittle material of the second spring member 30.

When a first spring member 23 formed of a ductile material and a second spring member 30 formed of a brittle material are connected to a movable upper electrode 20 as in the present example, a distance between the capacitance electrodes in a state in which the upper electrode 20 is pulled up (hereinafter referred to as an up state) is substantially determined by the spring constant k2 of the second spring member 30 which uses a brittle material.

Creep phenomenon rarely occurs in the second spring member 30 formed of a brittle material. Accordingly, even when the MEMS device is repeatedly driven a plurality of times, fluctuation in distance between the capacitance electrodes (between the upper electrode 20 and the lower electrode 12) in the up state is small. Creep of a material is the phenomenon of a member to increase in distortion (change in shape) across the ages or under the influence of a stress.

Creep phenomenon occurs in the first spring member 23 formed of a ductile material after being driven a plurality of times. The spring constant k1 of the first spring member 23, however, is set lower than the spring constant k2 of the second spring member 30 which uses a brittle material. Accordingly, change in shape (distortion) of the first spring member 23 which uses a ductile material does not cause a significant effect on the distance between the capacitance electrodes in the up state.

It is therefore possible to use a conductive ductile material as the movable upper electrode (movable structure) 20 in this example. That is, since a material with a low resistance rate can be used as the movable upper electrode 20 with no consideration for creep phenomenon, loss of the MEMS device can be reduced.

[Manufacturing Method]

A method of manufacturing a MEMS device according to the present embodiment will now be described.

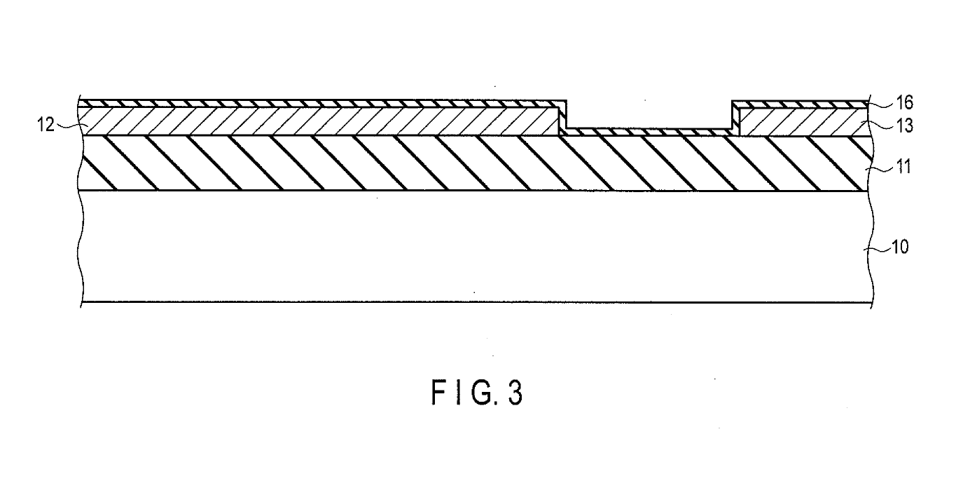

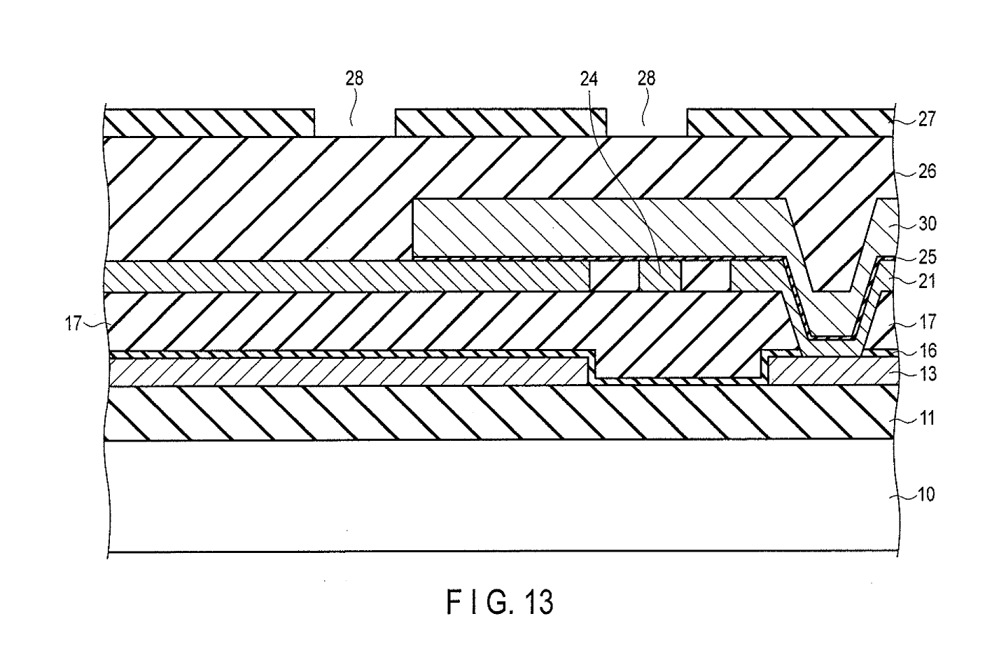

FIGS. 3-13 are cross-sectional views taken along the direction of arrows II-II of FIG. 1, illustrating the method of manufacturing the MEMS device according to the present embodiment.

As shown in FIG. 3, an interlayer insulating layer 11 is formed on a supporting substrate 10 by a plasma-enhanced chemical vapor deposition (P-CVD) process, for example. The interlayer insulating layer 11 is formed of SiOx derived from SiH₄ or TEOS, for example. After that, a metal layer is evenly formed on the interlayer insulating layer 11 by a sputtering process, for example. The metal layer is formed of Al, an alloy containing Al as the main component, Cu, Au, or Pt.

Next, the metal layer is patterned by lithography and reactive ion etching (RTE). Thereby, a lower electrode 12 is formed on the interlayer insulating layer 11. At the same time, a dummy layer 13 and wirings 14, 15 are formed on the interlayer insulating layer 11.

After that, an insulating layer 16 is formed on the entire surface by a P—CVD process, for example. Thereby, surfaces of the lower electrode 12, the dummy layer 13, and the wirings 14, 15 are covered with the insulating layer 16. The insulating layer 16 is formed of SiOx, SiN, or a high-k material.

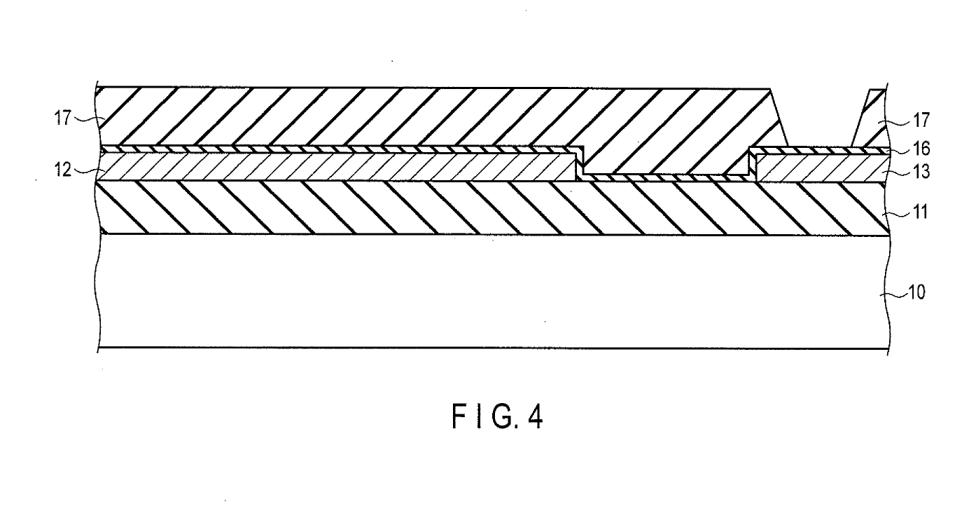

Next, as shown in FIG. 4, a first sacrifice layer 17 is applied on the insulating layer 16. The first sacrifice layer 17 is formed of an organic material such as polyimide. Next, the first sacrifice layer (coated film) 17 is cured and hardened, and then patterned by lithography and RIE, for example, so as to expose a part of the insulating layer 16. After that, the exposed part of the insulating layer 16 is etched by RIE, for example. Thereby, an opening portion is formed in the first sacrifice layer 17 and the insulating layer 16 in a position in which a first anchor member 22 and a second anchor member 21 are to be formed (above the wiring 15 and the dummy layer 13). In this case, the dummy layer 13 does not need to be exposed.

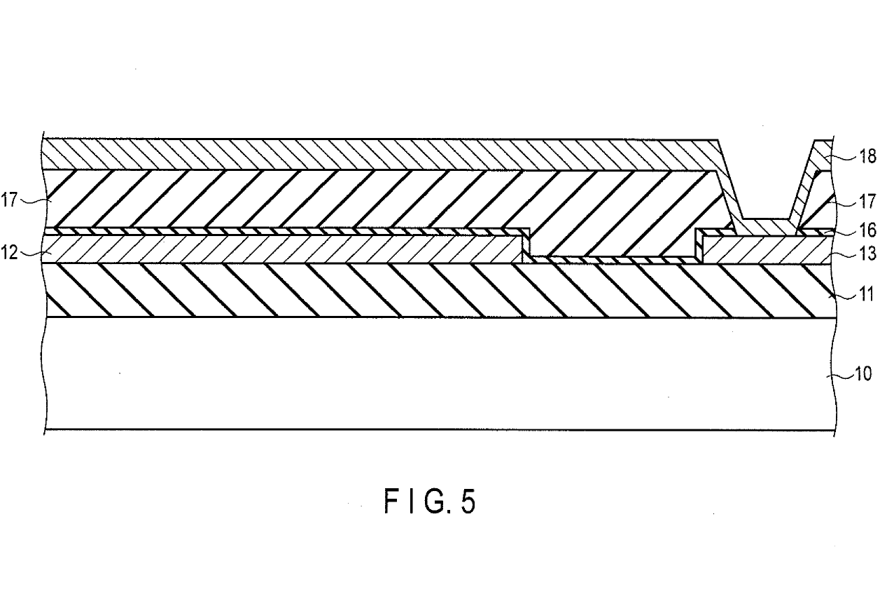

Next, as shown in FIG. 5, a metal layer 18 is formed on the entire surface, by a sputtering process, for example. More specifically, the metal layer 18 is formed on an upper surface of the first sacrifice layer 17 outside the opening portion, on a side surface of the first sacrifice layer 17 inside the opening portion, and on an upper surface of the dummy wiring 13 inside the opening portion. The metal layer 18 is formed so as to contact the wiring 15 and the dummy layer 13 on a bottom surface of the opening portion. The metal layer 18 is formed of Al, an alloy containing Al as the main component, Cu, Au, or Pt, for example. The metal layer 18 is a layer which is to be processed into an upper electrode 20, a second anchor member 21, a first anchor member 22, and a first spring member 23 in subsequent steps.

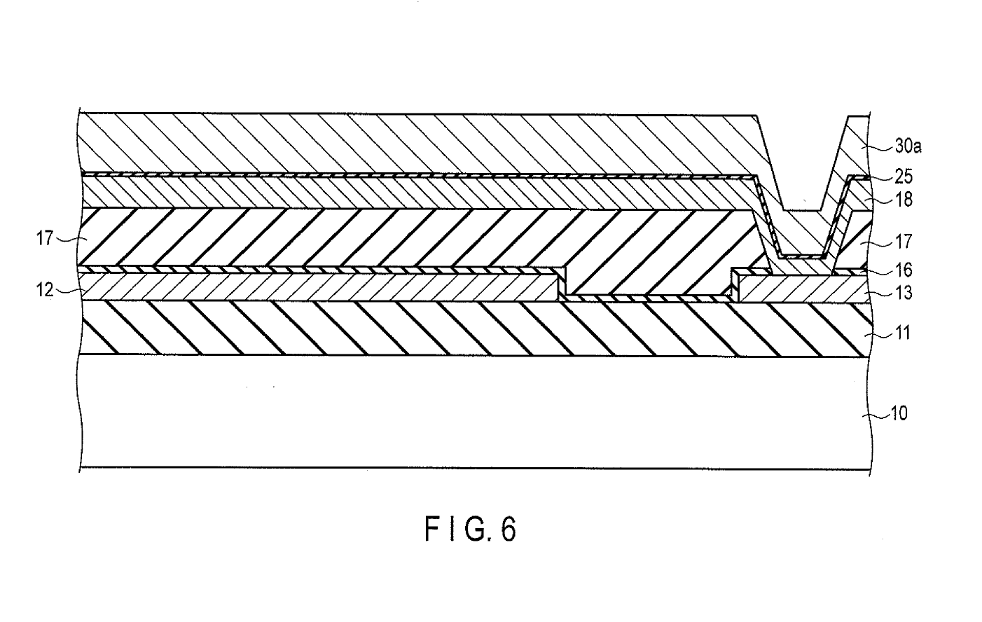

Next, as shown in FIG. 6, a first cap film such as a silicon oxide film) 25 is formed on the metal layer 18, and then a layer 30a, which is to be processed into a second spring member 30, is formed on the first cap film 25 by a P-CVD process, for example. The layer 30a is formed of a brittle material, for example. Examples of brittle materials include SiOx, SiN, and SiON.

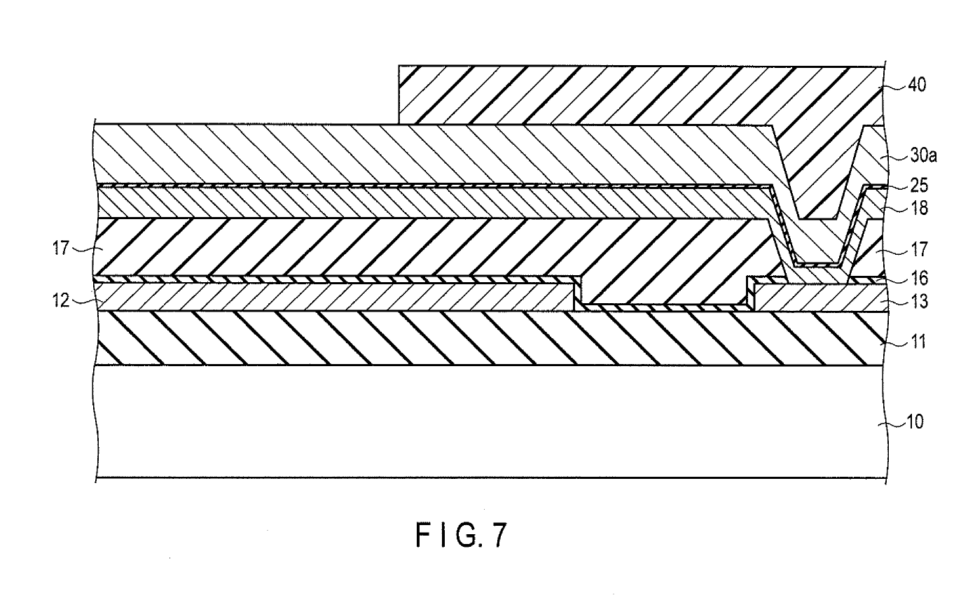

Next, as shown in FIG. 7, a resist 40 is formed on the layer 30a, and then the resist 40 is patterned by lithography, for example. In this case, the resist 40 remains in a region on which a second spring member 30 is to be formed.

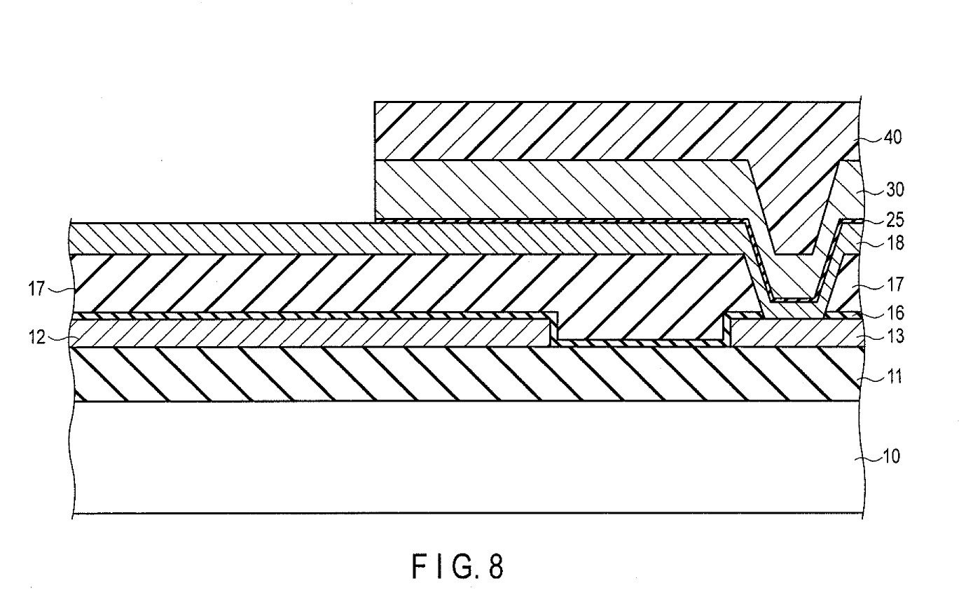

Next, as shown in FIG. 8, the layer 30a formed of a brittle material is etched by RIE using the resist 40 as a mask, for example, and then the first cap film 25 is etched. Thereby, a second spring member 30 which connects an upper electrode 20 and a second anchor member 21, which are to be formed later, is formed.

In this case, the metal layer 18, which is to form an upper electrode 20, a second anchor member 21, a first anchor member 22, and a first spring member 23 later, is not processed and is formed on the entire surface. Accordingly, the metal layer 18 is horizontally formed without steps with a certain thickness in a region A of the second spring member 30, which is to be formed thereon. In other words, a lower surface of the region A of the second spring member 30 is formed flat. An upper surface of the region A of the second spring member 30 may be formed flat, as well as the lower surface.

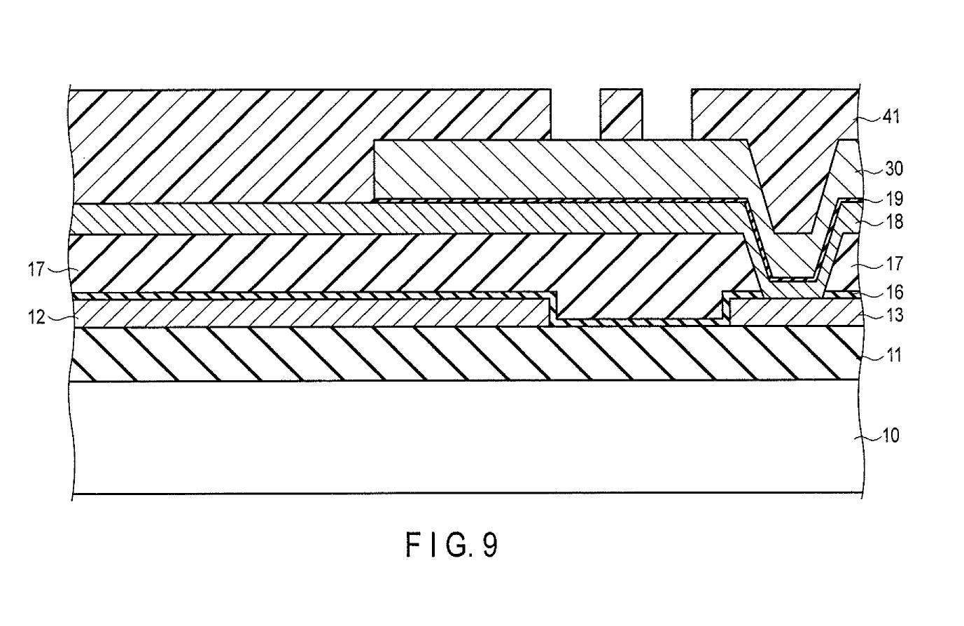

Next, as shown in FIG. 9, a resist 41 is formed on the entire surface and is then patterned by lithography, for example. In this case, the resist 41 remains in a region on which an upper electrode 20, a first anchor member 22, a second anchor member 21, a wiring 23, and a reinforcing member 24 are to be formed. As will be described later, since the metal layer 18 is etched by isotropic etching, the resist 41 is formed so as to be greater than a region in which an upper electrode 20, a first anchor member 22, a second anchor member 21, and a wiring 23 are to be formed.

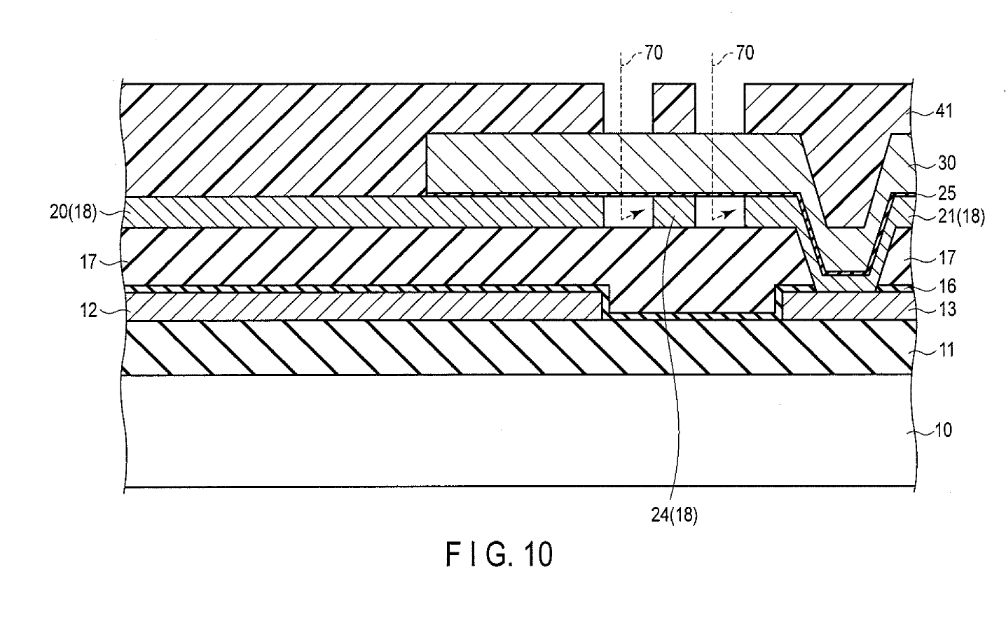

Next, as shown in FIG. 10, the metal layer 18 and the first cap film 25 are patterned by isotropic etching, such as wet etching. Thereby, an upper electrode 20 is formed on the first sacrifice layer 17 so as to be opposed to the lower electrode 12.

Further, a second anchor member 21 is formed in the opening portion on the dummy layer 13. A reinforcing member 24 is formed on the first sacrifice layer 17 in a region between the upper electrode 20 and the second anchor member 21. In other words, the reinforcing member 24 is formed on a lower surface of the second spring member 30 in the region between the upper electrode 20 and the second anchor member 21. A first anchor member 22 is formed in the opening portion on the wiring 15, and a first spring member 23, which connects the upper electrode 20 and the first anchor member 22, is formed on the first sacrifice layer 17.

In this case, the metal layer 18 is not necessary in a region other than the regions in which the upper electrode 20, the second anchor member 21, the reinforcing member 24, the first anchor member 22, and the first spring member 23 are formed. That is, the metal layer 18 positioned under the second spring member 30 (metal layer 18 positioned behind the second spring member 20) needs to be removed except for the part which is to be processed into the reinforcing member 24. For this reason, the metal layer 18 is etched not by anisotropic etching but by isotropic etching, as described above. Isotropic etching of the metal layer 18 is performed by supplying an etching liquid 70 from a part of the second spring member 30 that is not covered with the resist 41 to the metal layer 18 provided thereunder, since the width (lateral dimension) of the second spring member 30 is small.

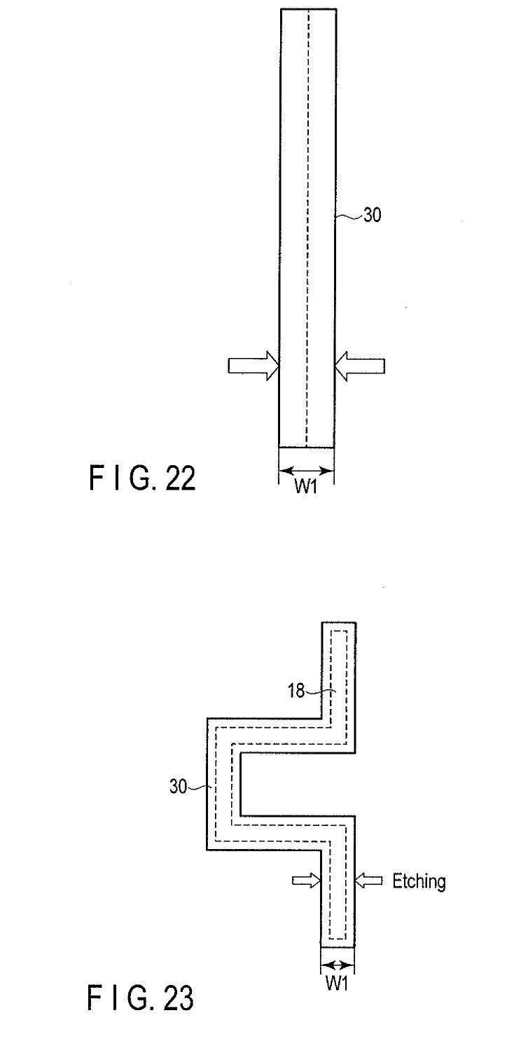

Furthermore, as shown in FIG. 22, in isotropic etching, the unnecessary part of the metal layer 18 positioned under the second spring member 30 in a region not covered by the resist 41 is etched from the sides. Therefore, in order to fully remove the unnecessary part of the metal layer 18 positioned under the second spring member 30, an amount of etching performed by isotropic etching should be at least half (W1/2) a width W1 of the second spring member 30 or greater, for example.

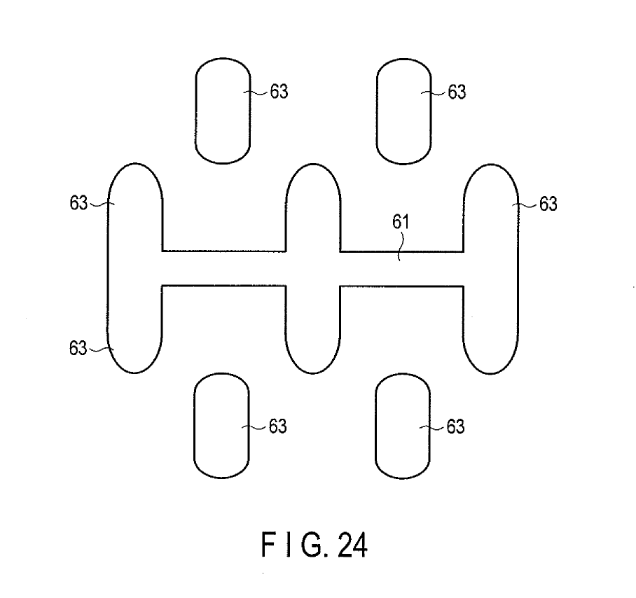

On the other hand, as shown in FIG. 23, a metal layer pattern (such as the first spring member 23) with the minimum width of the metal layer 18 is formed by forming a resist 41 thereon and performing isotropic etching from the sides. In this case, an amount of etching performed from the sides of the first spring member 23 is comparable to the amount of etching (W1/2) of the second spring member 30. Therefore, in order to form (leave) the first spring member 23, a width W2 of the resist 41 provided thereon is made greater than a width W1 of the second spring member 30.

Before isotropic etching is performed, the metal layer 18 may be etched by anisotropic etching such as RIE, using the resist 41 and the second spring member 30 as a mask. That is, after the metal layer 18 positioned in a region other than the region under the resist 41 and the second spring member 30 is removed by RIE, the metal layer 18 positioned under the second spring member 30 is removed by isotropic etching. Usually, RIE (anisotropic etching) is easier to control than anisotropic etching. Therefore, by performing etching by RIE in advance, the amount of etching performed by isotropic etching can be reduced, thereby improving controllability of etching.

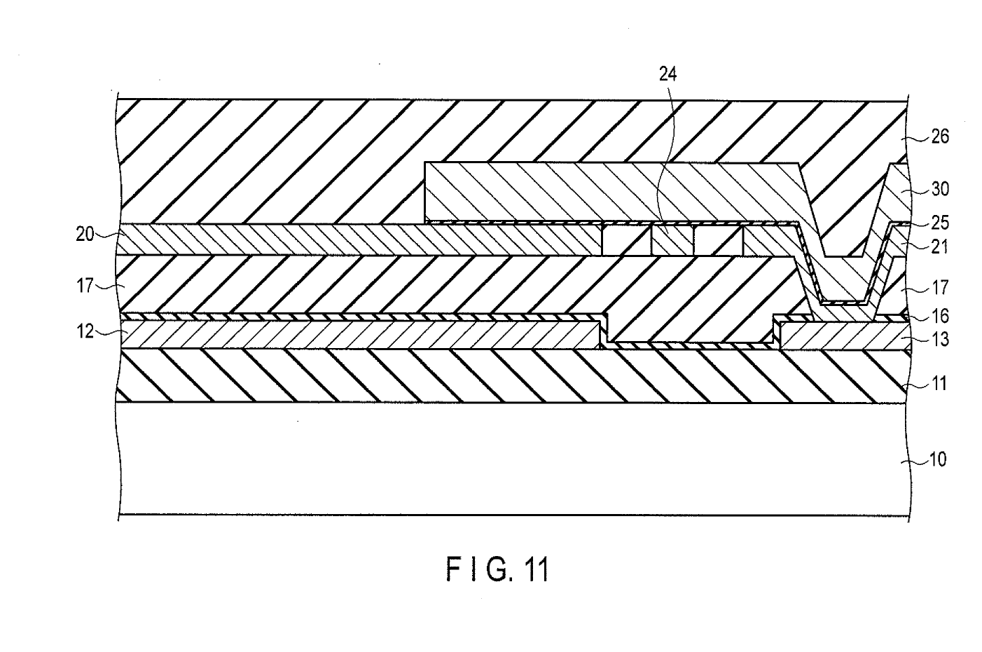

Next, as shown in FIG. 11, the resist 41 is removed and a second sacrifice layer 26 is applied so as to cover a movable part of the MEMS device, and the second sacrifice layer 26 (coated film) is cured and hardened. The second sacrifice layer 26 is formed of an organic material such as polyimide.

After that, an insulating second cap film 27 (dome structure) is formed on the second sacrifice layer 26. The second cap film 27 is an inorganic thin film (such as a silicon oxide film) of hundreds of nm to tens of μm, for example. The second cap film 27 is formed by a CVD process, for example.

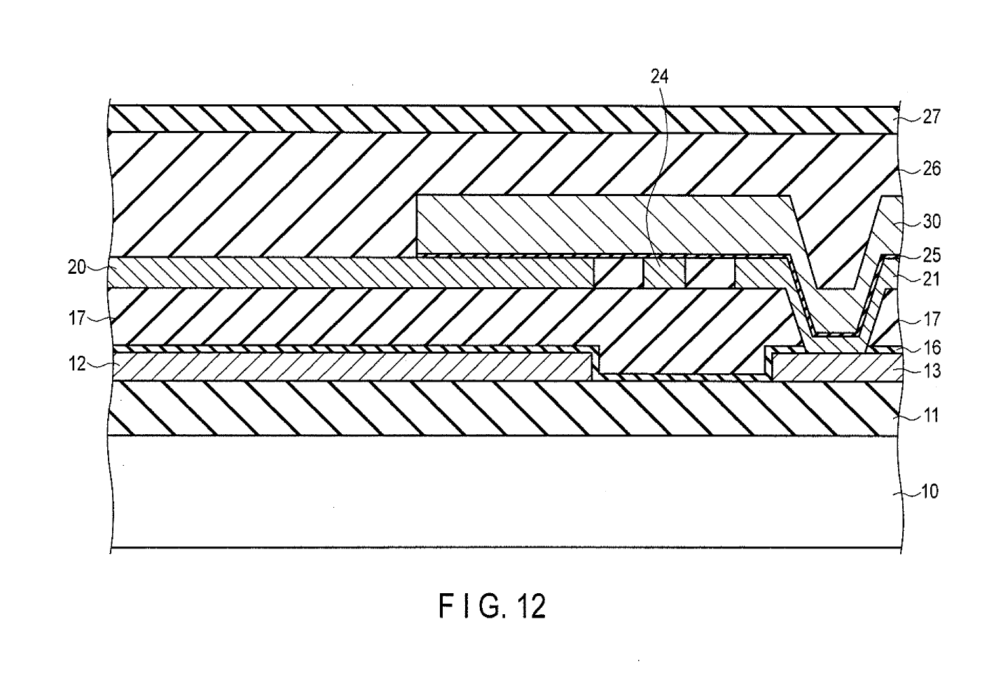

Next, as shown in FIG. 12, a plurality of through holes 28 are formed in the second cap film 27 by etching the second cap film 27 by RIE or a wet treatment using a resist pattern, not shown, as a mask. The resist pattern, not shown, is formed by a usual photolithography process.

Next, after the resist 41 is removed, the first sacrifice layer 17 and the second sacrifice layer 26 are removed by isotropic dry etching, such as an O₂-base or Ar-base ashing process, and thereby the first spring member 23, the second spring member 30, and the upper electrode 20 will be in a floating state. Thus, a movable region of the upper electrode 20 shown in FIG. 2 is formed in the region between the lower electrode 12 and the upper electrode 20 (below and above the upper electrode 20), and the MEMS device according to the present embodiment is obtained.

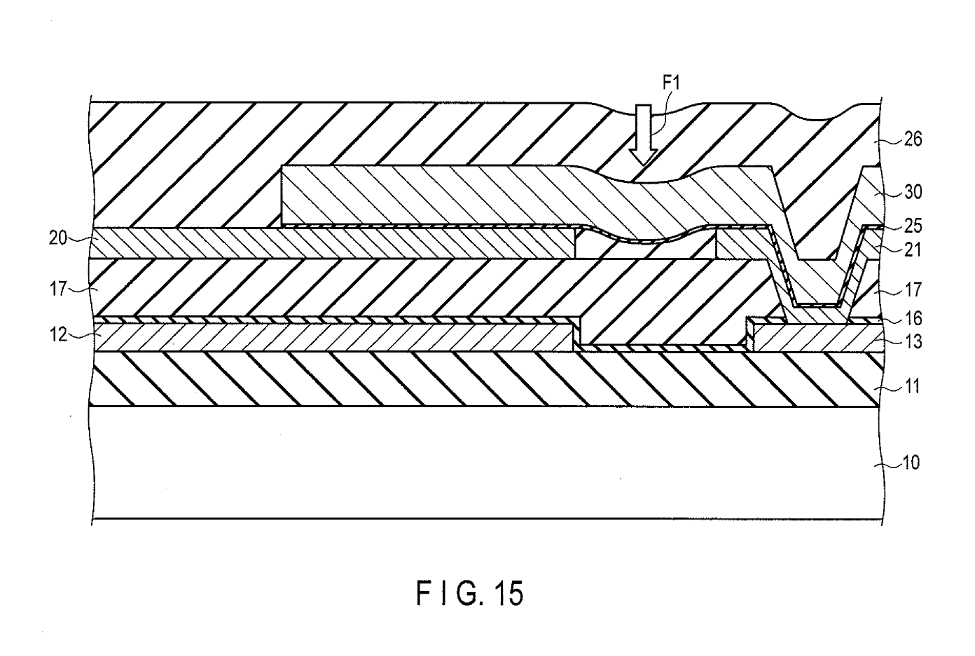

FIG. 15 is a cross-sectional view of a comparative example corresponding to the cross-sectional view (step of applying and curing a second sacrifice layer 26) of FIG. 11. In the comparative example, a reinforcing member does not exist below a lower surface of the second spring member 30 in a region between an upper electrode 20 and a second anchor member 21. Therefore, when the second sacrifice layer 26 is cured, a downward force F1 is applied to the second spring member 30, and the second spring member 30 elastically deforms.

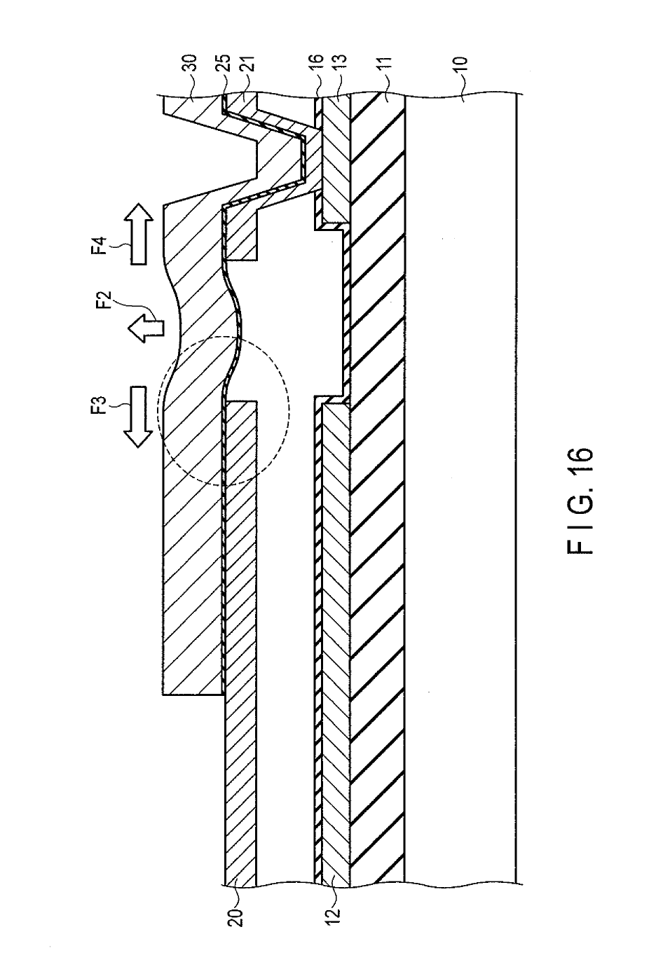

When the first sacrifice layer 17 and the second sacrifice layer 26 are removed in this state, as shown in FIG. 16, the elastically deformed second spring member 30 will try to return to the original shape. In this case, an upward force F2 and lateral forces F3, F4 are exerted on the second spring member 30. Since the second spring member 30 contacts the upper electrode 20, a force is exerted on the upper electrode 20 as well.

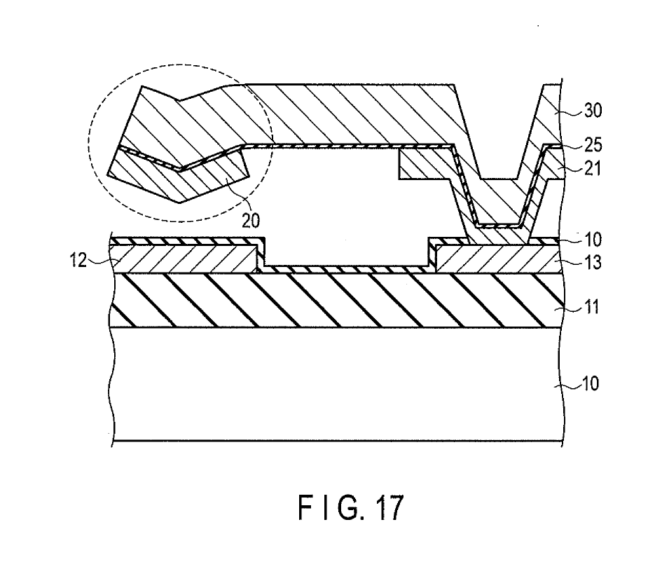

As a result, V-shaped deformation occurs in the upper electrode 20, as shown in FIG. 17, for example. This means that the upper electrode 20 cannot be formed in a shape with desired characteristics. Deformation of the upper electrode 20 can occur in a hole portion for example, he first hole portion 61) as well.

However, in the present embodiment, since the reinforcing member 24 configured to reinforce strength of the second spring member 30 exists, deformation of the second spring member 30 is suppressed during removing of the sacrifice layer. As a result, elastic deformation of the upper electrode 20 is suppressed, and the upper electrode 20 can be formed in a shape with desired characteristics.

While the reinforcing member 24 is not necessarily needed after the sacrifice layer is removed, the reinforcing member 24 may be left in anticipation of the effect of the reinforcing member 24 reinforcing the second spring member 30 even after completion of removal of the sacrifice layer.

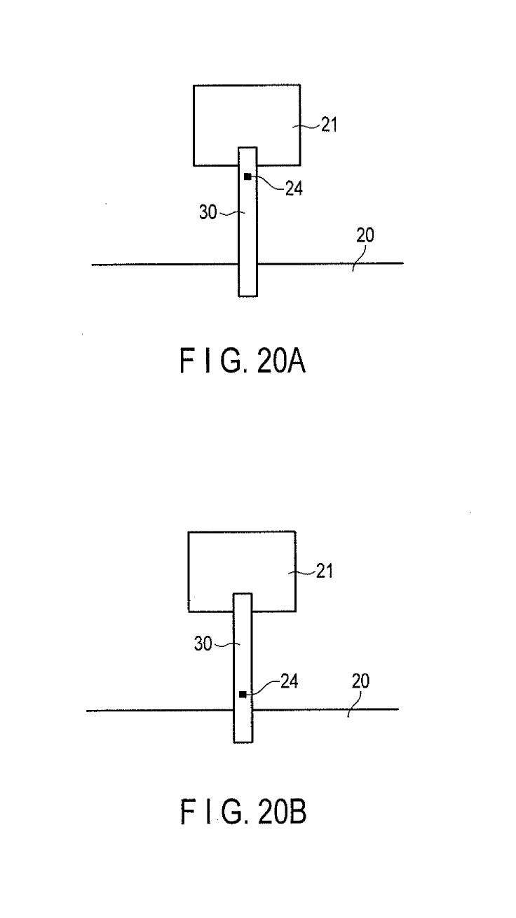

While the reinforcing member 24 is provided on the lower surface of the second spring member 30 in a central position between the second anchor member 21 and the upper electrode 20 in the present embodiment, the reinforcing member 24 may be provided on a lower surface of the second spring member 30 in a position on the side of the second anchor member 21, as shown in FIG. 20A, or on a lower surface of the second spring member 30 in a position on the side of the upper electrode 20, as shown in FIG. 20B. Further, the reinforcing member 24 may be provided on two or all of the above-described three lower surfaces.

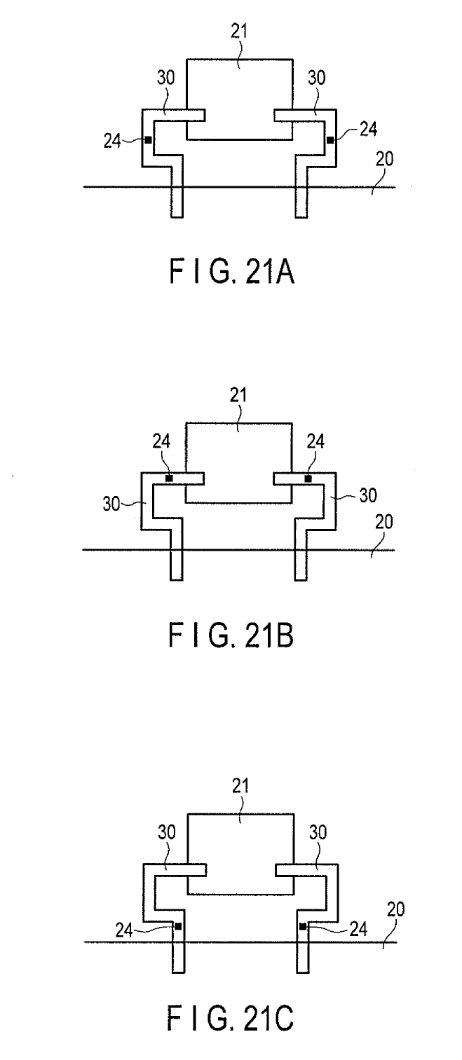

In addition, in the case of the planar pattern shown in FIG. 19, the reinforcing member 24 may be provided on at least one of a lower surface of the second spring member 30 in a central position between the second anchor member 21 and the upper electrode 20, as shown in FIG. 21A, a lower surface of the second spring member 30 in a position on the side of the second anchor member 21 as shown in FIG. 21B, and a lower surface of the second spring member 30 in a position on the side of the upper electrode 20 as shown in FIG. 21C, for example.

A structure and a manufacturing method of the MEMS device of the present embodiment are not limited to those described above.

In the present embodiment, the second spring member 30 formed of a brittle material does not need to be formed in a single-layer structure, for example. From the viewpoint of adhesion between the upper electrode 20 and the second anchor member 21, the second spring member 30 may have a laminated structure in which the lower layer is formed of SiOx and the upper layer is formed of SiN. In this case, after the SiN layer is etched, the second spring member 30 can be patterned by etching the SiOx layer.

Moreover, the present embodiment is applicable to a system of applying a voltage to between the upper electrode 20 and the lower electrode 20 and driving the electrodes with an electrostatic force, but is also applicable to a system of forming the upper electrode 20 and the lower electrode 12 in a laminated structure of different types of metals and driving the electrodes with a piezoelectric force thereof.

Moreover, the present embodiment is also applicable to a MEMS switch, as well as variable capacitance. In this case, a part of a capacitor insulating layer (insulating layer 16) formed on the lower electrode 12, e.g. a part contacting the upper electrode 20, is removed by etching, and thereby a surface of the lower electrode 12 is exposed. Thereby, a switch is formed by the upper electrode 20 and the lower electrode 12, and the switch is activated by driving the upper electrode 20.

While a case has been described where two electrodes, the movable upper electrode 20 and the fixed lower electrode 12, are provided in the present embodiment, the present embodiment is applicable to a case where both of the electrodes are movable, and is also applicable to a case where three or more electrodes (a fixed upper electrode, a fixed lower electrode, and a movable intermediate electrode, for example) are provided.

The area of the upper electrode 20 and the lower electrode 12 in the plane can be set as appropriate. A MEMS structure formed of an upper electrode 20 and a lower electrode 12 may be arranged on a transistor circuit such as a CMOS, for example. Further, a dome structure that covers and protects the MEMS structure may be formed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An electrical component comprising:
a substrate; and
a MEMS device provided on the substrate, the MEMS device comprising:
a first electrode fixed on the substrate;
a second electrode arranged above the first electrode so as to be opposed to the first electrode and configured to be movable in a vertical direction;
an anchor member provided on the substrate and configured to support the second electrode;
a spring member continuously formed from a region on an upper surface of the second electrode to a region on an upper surface of the anchor member and configured to connect the second electrode and the anchor member; and
a reinforcing member provided on a lower surface of the spring member and configured to reinforce strength of the spring member.

2. The electrical component according to claim 1, wherein the lower surface of the spring member is flat from the region on the upper surface of the second electrode to the region on the upper surface of the anchor member.

3. The electrical component according to claim 1, wherein the spring member comprises a brittle material.

4. The electrical component according to claim 3, wherein the brittle material is an insulator.

5. The electrical component according to claim 4, wherein the brittle material contains a silicon oxide, a silicon nitride, or a silicon oxynitide.

6. The electrical component according to claim 3, further comprising:
a spring member provided on the substrate, configured to support the second electrode, and comprises a ductile material.

7. The electrical component according to claim 6, wherein a spring constant of the spring member comprising the brittle material is greater than a spring constant of the first spring member comprising the ductile material.

8. The electrical component according to claim 6, wherein the ductile material is an electrical conductor.

9. The electrical component according to claim 8, wherein the ductile material contains Al, an alloy containing Al as the main component, Cu, Au, or Pt.

10. The electrical component according to claim 1, wherein the second electrode includes a first hole portion extending in a first direction, the first direction is a longitudinal direction of the second electrode.

11. The electrical component according to claim 10, wherein the first hole portion is provided in a central part in a lateral direction of the second electrode.

12. The electrical component according to claim 10, wherein the second electrode further includes a second hole portion extending in a second direction, the second direction is orthogonal to the longitudinal direction of the second electrode.

13. The electrical component according to claim 12, wherein the second hole portion is provided between the first hole portion and a peripheral part of the first electrode.

14. The electrical component according to claim 1, wherein the reinforcing member is provided on at least one of a lower surface of the spring member in a position on a side of the anchor member, a lower surface of the spring member in a position on a side of the second electrode, and a lower surface of the spring member in a central position between the anchor member and the second electrode.

15. The electrical component according to claim 1, further comprising: an insulating film provided above the second electrode, and wherein the insulating film and the substrate are configured to house the MEMS device.

16. A method of manufacturing an electrical component including a method of manufacturing a MEMS device on a substrate, the method of manufacturing the MEMS device comprising:
forming a first electrode fixed on the substrate;
forming a first sacrifice layer on an entire surface;
forming a metal layer on the first sacrifice layer;
forming a spring member on the metal layer; and
forming a second electrode and an anchor member which are connected by the spring member, and forming a reinforcing member configured to reinforce strength of the spring member on a lower surface of the spring member, by etching the metal layer.

17. The method according to claim 16, wherein etching of the metal layer is performed by using a wet treatment.

18. The method according to claim 16, further comprising:
forming a second sacrifice layer on an entire surface after forming the second electrode, the anchor member, and the reinforcing member;
curing the second sacrifice layer;
forming an insulating film on the second sacrifice layer; and
removing the first and second sacrifice layers.

19. The method according to claim 18, wherein the second sacrifice layer includes a coated film.

20. The method according to claim 18, wherein removing of the first and second sacrifice layers is performed by an asking process including oxygen.
